(19) United States
(12) Patent Application Publication
(10) Pub. No.: US 2018/0330998 A1
(43) Pub. Date: Nov. 15, 2018

(54) PROCESS FOR FABRICATING SILICON-GERMANIUM STRIPS

(71) Applicant: STMicroelectronics (Crolles 2) SAS, Crolles (FR)

(72) Inventor: Loic GABEN, Busque (FR)

(73) Assignee: STMicroelectronics (Crolles 2) SAS, Crolles (FR)

(21) Appl. No.: 15/973,969

(22) Filed: May 8, 2018

(30) Foreign Application Priority Data
May 10, 2017 (FR) 1754104

(51) Int. Cl. H01L 21/84; H01L 21/225; H01L 21/02; H01L 21/311; H01L 29/06; H01L 29/66; H01L 29/78; H01L 27/12

(52) U.S. Cl. CPC H01L 21/845; H01L 21/2254; H01L 21/02236; H01L 21/02255; H01L 21/02164; H01L 27/1211; H01L 29/0673; H01L 29/6681; H01L 29/6653; H01L 29/66553; H01L 29/7853; H01L 21/31111

(57) ABSTRACT

A strip or portions of a strip of silicon-germanium is made by first producing a strip of silicon suspended above a substrate. At least a portion of the strip of silicon is with a layer of silicon-germanium. Germanium enrichment of the portion of the strip of silicon is accomplished through a thermal oxidation. The resulting silicon oxide formed during the thermal oxidation is then removed.

### PRIORITY CLAIM

This application claims the priority benefit of French Application for Patent No. 1754104, filed on May 10, 2017, the disclosure of which is hereby incorporated by reference in its entirety to the maximum extent allowable by law.

### TECHNICAL FIELD

The present invention relates to a process for fabricating silicon-germanium nanowires and, more particularly, to a process for fabricating silicon nanowires and silicon-germanium nanowires and/or nanowires comprising silicon portions and silicon-germanium portions.

### BACKGROUND

Semiconductor nanowires suspended above a substrate or semiconductor fins are commonly used to fabricate channel regions of surrounding gate transistors or FinFET transistors. The semiconductor material is, for example, monocrystalline silicon-germanium or silicon.

A known process for fabricating semiconductor nanowires comprises, in the case of silicon nanowires for example, the following successive steps:
alternately depositing layers of silicon and layers of silicon-germanium on a substrate, starting with a silicon-germanium layer, the thickness of these layers being equal to the thickness of the nanowires that are desired to be formed;
etching these layers in order to form one or more strips having the thickness of the future nanowires, each strip being connected at its ends to pads that are wider than the strip; and
selectively etching the silicon-germanium layers with respect to the silicon layers such that portions of the silicon-germanium layers remain at the pads and form supports for the silicon strips, these strips then forming the nanowires.

This process can be adapted to the formation of silicon-germanium nanowires. For this purpose, the layers of silicon and silicon-germanium are deposited starting with a layer of silicon. Next, the silicon is selectively etched with respect to the silicon-germanium. In order to selectively etch silicon with respect to silicon-germanium, it is known practice to use wet etching processes. However, such etching processes are generally not very selective and leave quite rough silicon-germanium surfaces, while processes for etching silicon-germanium with respect to silicon are themselves selective.

A known fabrication process for fabricating fins comprises the deposition followed by the etching of a layer of silicon or silicon-germanium on a substrate. The thickness of the layer is equal to that of the fin that is desired to be formed.

One drawback of these processes for forming nanowires or fins is that, in the case that it is desired to produce silicon and silicon-germanium nanowires or fins suspended above one and the same substrate, it is necessary to make provision for a large number of fabrication steps.

Another drawback of this process is that it does not allow the straightforward fabrication of a nanowire or a fin comprising silicon portions and silicon-germanium portions.

There is accordingly a need in the art for a fabrication process allowing the simultaneous fabrication of silicon and silicon-germanium nanowires or fins. It would an advantage if such a fabrication process would allow for at least some of the aforementioned drawbacks to be overcome.

### SUMMARY

An embodiment comprises a process for fabricating strips or portions of strips of silicon-germanium comprising the following successive steps: producing strips of silicon suspended above a substrate; surrounding said strips or portions of strips of silicon with a layer of silicon-germanium; carrying out germanium enrichment by thermal oxidation; and removing a silicon oxide formed during the thermal oxidation.

According to one embodiment, the process additionally comprises a step of masking all or part of the silicon strips in order to protect the silicon strips from the steps of deposition of silicon-germanium and enrichment by thermal oxidation.

According to one embodiment, the silicon-germanium layer is formed by selective epitaxy.

According to one embodiment, the width of the silicon strips is between 2 and 50 nm and the thickness thereof is between 5 and 20 nm.

According to one embodiment, the substrate is an insulator.

According to one embodiment, the thermal oxidation is carried out at a temperature of between 600 and 1200° C.

According to one embodiment, the silicon oxide is removed by means of a wet etching process.

According to one embodiment, the silicon strips are silicon fins.

According to one embodiment, the silicon strips are silicon nanowires.

An embodiment comprises a structure comprising an assembly of semiconductor nanowires suspended at the same height above a substrate, some of said nanowires being at least partially made of silicon and some of said nanowires being at least partially made of silicon-germanium.

An embodiment comprises a structure comprising an assembly of semiconductor fins, some of said fins being at least partially made of silicon and some of said fins being at least partially made of silicon-germanium.

### BRIEF DESCRIPTION OF THE DRAWINGS

These features and advantages, along with others, will be presented in detail in the following description of particular embodiments, provided without limitation and in relation to the appended figures among which:

FIGS. 1A to 1M illustrate the steps of one embodiment of a process for fabricating nanowires comprising silicon portions and silicon-germanium portions;

FIG. 2 illustrates one embodiment of nanowires comprising silicon portions and silicon-germanium portions; and

FIG. 3 illustrates one embodiment of a fin comprising silicon portions and silicon-germanium portions.

### DETAILED DESCRIPTION

The same elements have been referenced by the same references in the various figures. For the sake of clarity, only those elements which are of use in understanding the described embodiments have been shown and are described in detail.

In the following description, when reference is made to qualifiers of absolute position, such as the terms “left”, “right”, etc., or qualifiers of relative position, such as the terms “above”, “upper”, “lower”, etc., or to qualifiers of orientation, such as the terms “horizontal”, etc., reference is being made to the orientation of the figures. Unless specified otherwise, the expression “of the order of” signifies to within 10%, preferably to within 5%.

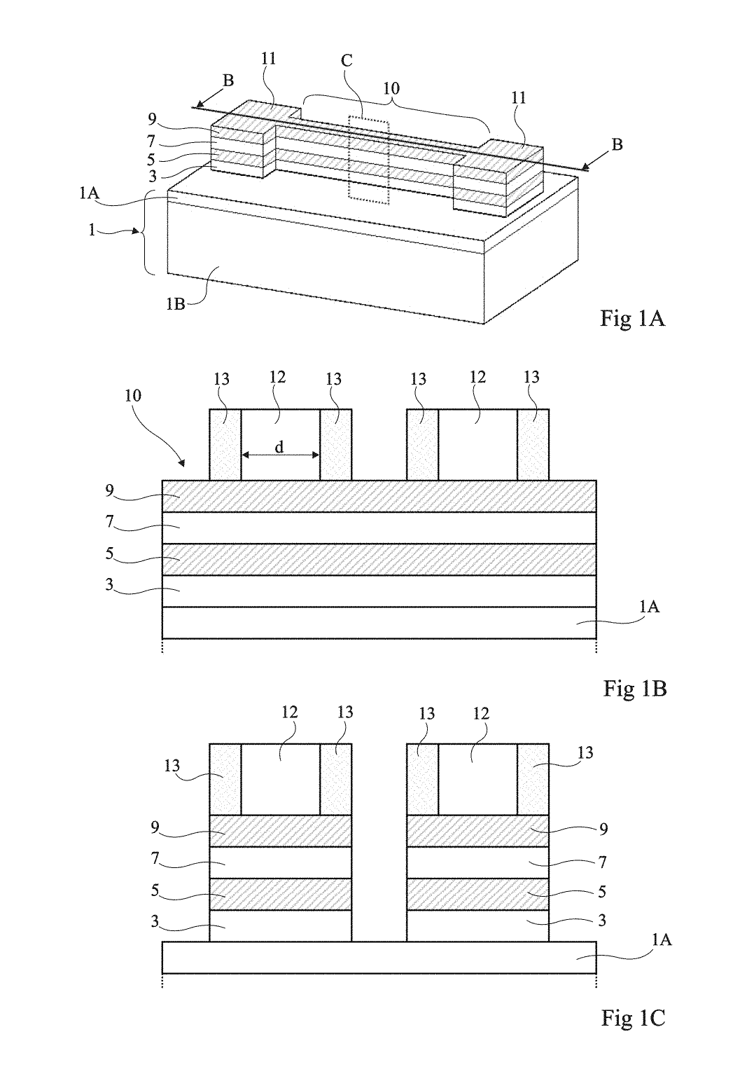

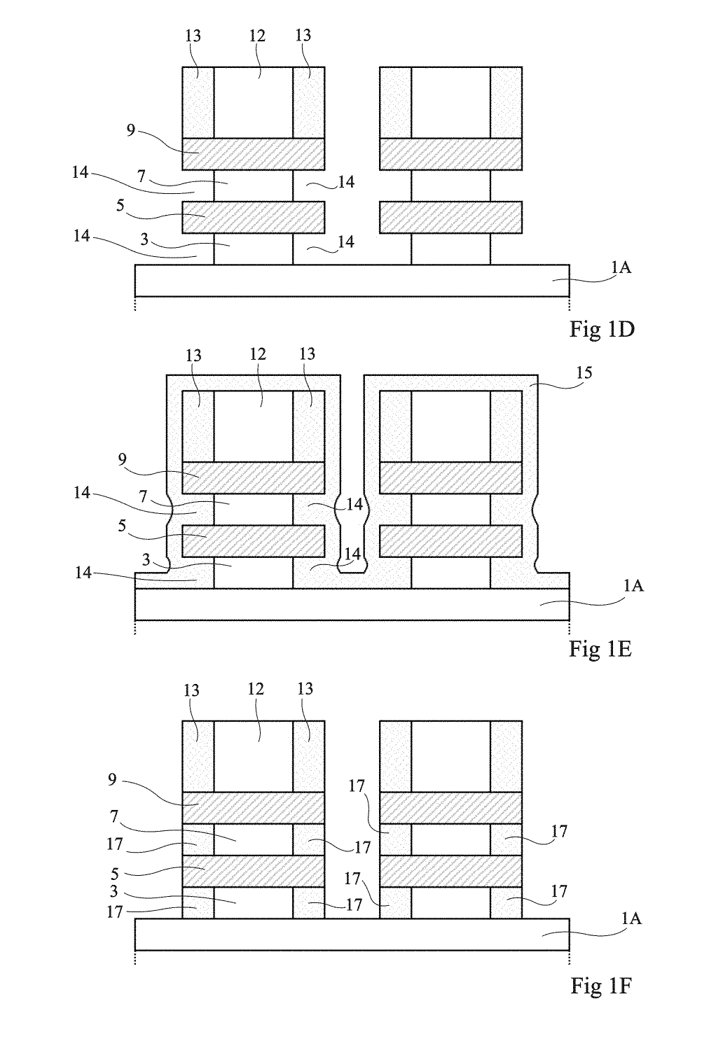

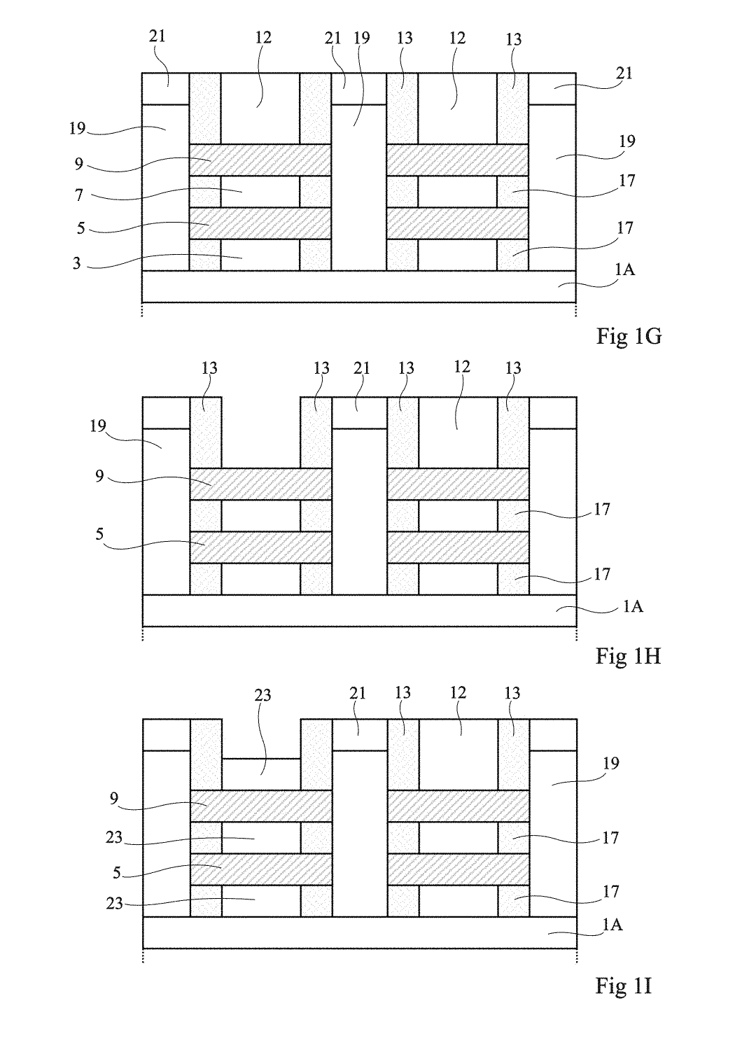

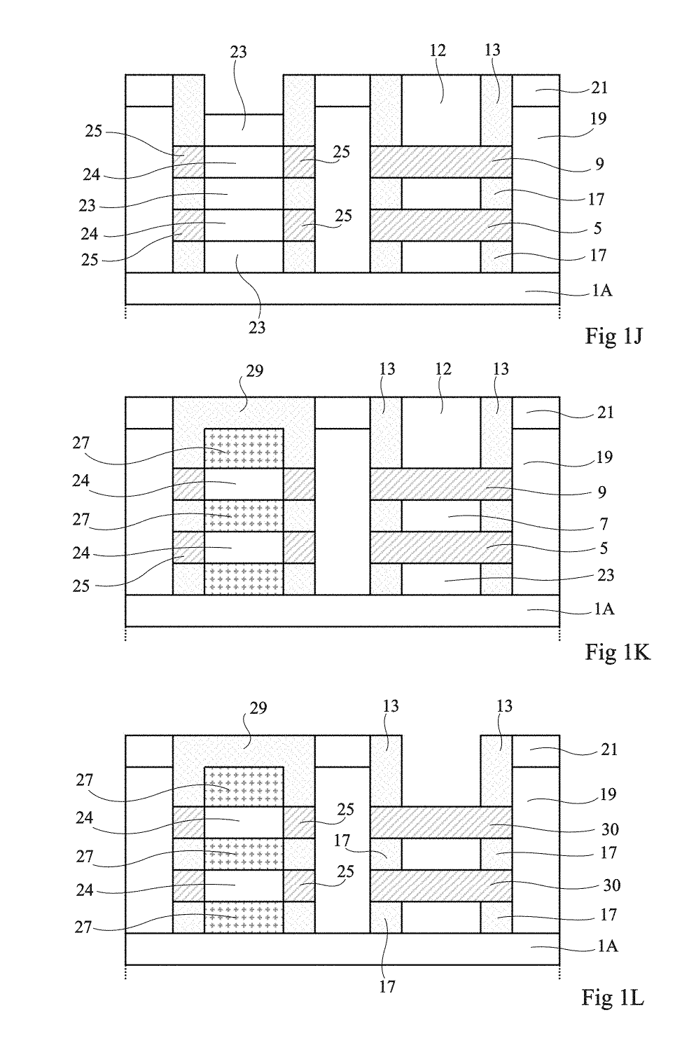

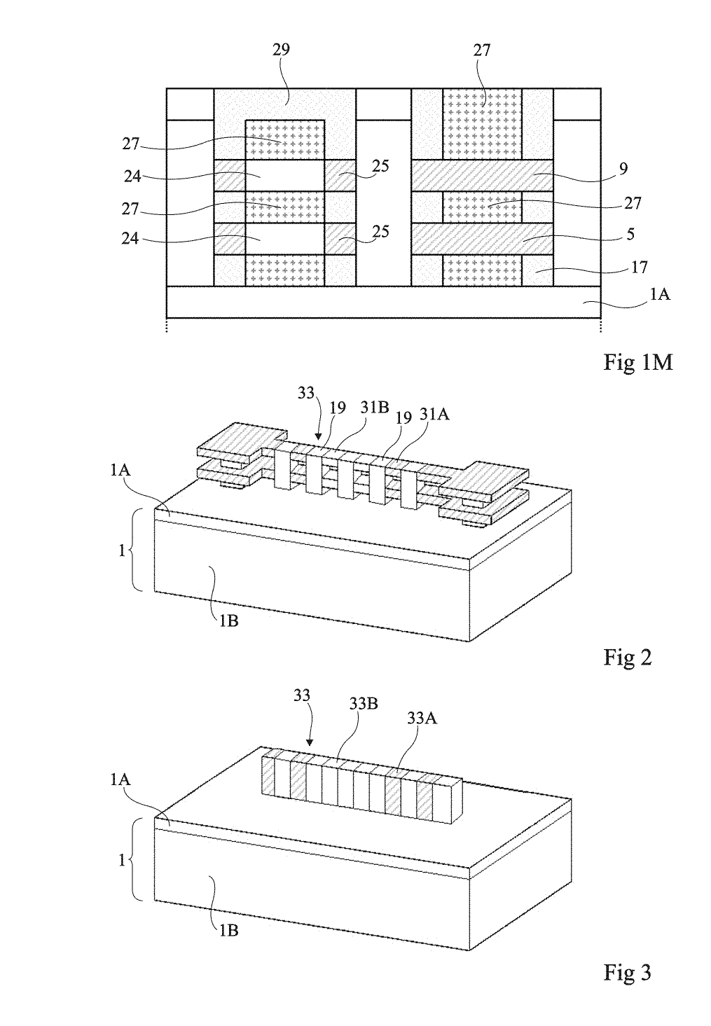

FIGS. 1A to 1M illustrate steps of one embodiment of a process for fabricating surrounding gate transistors comprising silicon or silicon-germanium nanowires. FIG. 1A is a perspective view. FIGS. 1B to 1N are views in cross section of a portion, demarcated by a frame C, of FIG. 1A along the plane BB. The arbitrary scale chosen for FIGS. 1B to 1M is not the same as that of FIG. 1A.

The process presented below relates to the fabrication of two portions made of silicon-germanium and silicon of two nanowires suspended one above the other above a substrate; however, as a variant, it would be possible to make provision for a single suspended nanowire or more than two suspended nanowires.

In the step of FIG. 1A, successive monocrystalline semiconductor layers 3, 5, 7 and 9 are deposited on a substrate 1. The substrate 1 comprises, for example, an insulating layer 1A resting on a semiconductor wafer 1B. The assembly of the semiconductor wafer 1B, the insulating layer 1A and the first semiconductor layer 3 may have been formed on the basis of an SOI (silicon-on-insulator) structure. The layers 3 and 7 are made of silicon-germanium. The layers 5 and 9 are made of silicon. The thickness of the layers 3, 5, 7 and 9 is for example between 5 and 20 nm, for example between 3 and 7 nm. The layers 3, 5, 7 and 9 are etched so as to form, when viewed from above, a strip 10, the width of which is between 5 and 50 nm, for example 10 nm, and comprising a superposition of four semiconductor strips 3, 5, 7 and 9. The strip 10 is connected at each of its ends to a pad 11 that is wider than the strip 10.

In the step of FIG. 1B, the locations at which the gates of the future transistors will be formed are defined by patterns 12 covering zones of the upper face and lateral faces of the strip 10 of FIG. 1. The patterns 12 are, for example, made by anisotropically etching polycrystalline silicon or on the basis of a photoresist which, once irradiated, transforms into an insulating material. By way of example, the resist used is hydrogen silsesquioxane (HSQ) which transforms into silicon oxide. The patterns 12 have a dimension d in the direction of the length of the strip 10 which is, for example, between 2 and 50 nm, of the order of 10 nm. The lateral faces of the patterns 12 are bordered by spacers 13. The spacers 13 are, for example, made of silicon nitride. The thickness of the spacers 13 is, for example, between 1 and 20 nm, for example 5 nm.

In the step of FIG. 1C, the strips 10 are etched using the patterns 12 and the spacers 13 as an etching mask. The strips 10 are, for example, etched by means of a vertical anisotropic etching process. By way of example, each strip 3, 5, 7 and 9 is etched in succession by means of a specific vertical anisotropic etching process.

In the step of FIG. 1D, the silicon-germanium strips 3 and 7 are etched laterally, selectively with respect to the silicon strips 5 and 9, such that, after etching, their dimension in the direction of the length of the strip 10 (horizontal direction in the figure) is smaller than that of the strips 5 and 9. The selective etching process attacks the edges of the strips 3 and 7 in order to form recesses 14 in their place. The recesses 14 are located between the ends of the strip 5 and the ends of the strip 9, and between the ends of the strip 5 and the insulating layer 1A. The strips 3 and 7 are, for example, etched by means of a selective etching process using hydrochloric acid.

In the step of FIG. 1E, an insulating layer 15 made of the same material as that of the spacers 13 is deposited conformally on the structure of FIG. 1D. Thus, the recesses 14 are filled by the layer 15. The layer 15 is, for example, made of silicon nitride. The layer 15 is, for example, deposited by means of a low pressure chemical vapor deposition technique.

In the step of FIG. 1F, the layer 15 is etched so as to form spacers 17 in the recesses 14.

In the step of FIG. 1G, a monocrystalline semiconductor layer 19 is formed by selective epitaxy from the lateral faces of the strips 5 and 9. The layer 19 extends up to a height that is lower than the height of the structure of FIG. 1F. The layer 19 is, for example, made of silicon or silicon-germanium. The layer 19 is, for example, n-doped or p-doped. The layer 19 forms the source and drain zones of the future transistors.

Next, a protective layer 21 is deposited on the structure and then polished in order to expose the upper faces of the patterns 12 and of the spacers 13. The layer 21 is for example made of silicon oxide or polycrystalline silicon.

In the step of FIG. 1H, certain patterns 12 are removed by selectively etching the structure of FIG. 1G while the other patterns 12 are protected. In FIG. 1H, the mask 12 on the left is removed and that on the right is retained. The steps described with reference to FIGS. 1H and 1K relate to the formation of a gate of a surrounding gate transistor comprising silicon-germanium nanowires. The steps described with reference to FIGS. 1L and 1M relate to the formation of a gate of a surrounding gate transistor comprising silicon nanowires. Thus, the steps described with reference to FIGS. 1H to 1K relate only to the left-hand portion of the figures.

The strips 3, 5, 7 and 9 are therefore exposed by selectively etching the patterns 12. The silicon-germanium strips 3 and 7 are etched selectively with respect to the silicon strips 5 and 9.

In the step of FIG. 1I, a silicon-germanium deposit 23 is grown by selective epitaxy from the exposed faces of the strips 5 and 9. The thickness of the silicon-germanium 23 is, for example, between one and three times the thickness of the layers 5 and 9.

In the step of FIG. 1J, the structure of FIG. 1I undergoes thermal oxidation. The structure is heated in the presence of oxygen, to a temperature of, for example, between 600 and 1200° C., for example of the order of 800° C. The silicon-germanium layer 23 loses its germanium atoms and is oxidized to become silicon oxide. The silicon strips 5 and 9 are enriched with germanium atoms. The strips 5 and 9 then form silicon-germanium nanowires 24.

Portions 25 of the strips 5 and 9 are protected by the spacers 13 and 17 and remain in silicon.

In the step of FIG. 1K, the silicon oxide 23 is removed by etching. The nanowires 24 form a channel region of a transistor. Finally, the gate of the transistor is formed, surrounding the nanowires 24 with a layer of a gate insulator and then a layer of a conductor. These two layers are referenced by the reference 27.

Next, an insulating cover 29 is deposited on the layers 27. The cover 29 protects the elements of the left-hand portion during the steps that will be described with reference to FIGS. 1L and 1M, which relate only to the right-hand portion of the figures.

In the step of FIG. 1L, the mask 12 deposited on the right-hand portion of FIG. 1L is removed, for example by selective wet etching. The strips 3, 5, 7 and 9 are then exposed. The silicon-germanium strips 3 and 7 are etched selectively with respect to the silicon strips 5 and 9. The strips 5 and 9 form silicon nanowires 30.

In the step of FIG. 1M, the gate of the transistor is finally formed, surrounding the nanowires 30 with a layer of a gate insulator and then a layer of a conductor. These two layers are referenced, as above, by the reference 27. The conductive and gate insulator materials may differ from those used above.

FIG. 2 is a perspective view of an example of two nanowires 31 comprising portions 31A made of silicon and portions 31B made of silicon-germanium which are formed by means of the process described with reference to FIGS. 1A to 1M. In FIG. 2, the gate conductor and insulator layers 27, the spacers 13, the covers 29 and the insulating layer 21 are not shown.

The portions 31A and 31B are at the same height, since they have been formed from the same silicon strips 5 and 9. The portions 31A and 31B are separated from one another by the layers 19. Each of the portions 31A and 31B of the nanowires 31 forms a channel region of a MOS transistor. The layer 19 forms the source and drain regions of these transistors. In FIG. 2, four channel regions are shown and allow four transistors having common drain and source regions, namely four transistors in series, to be formed.

One advantage of the process for fabricating surrounding gate transistors comprising silicon and silicon-germanium nanowires presented with reference to FIGS. 1A to 1M is that it allows rows of n-channel and p-channel MOS transistors connected in series to be formed. To achieve this, the silicon nanowire portions 31A are lightly p-doped and the silicon-germanium portions 31B are lightly n-doped, in order to form the channel regions of transistors. This type of structure may be used to form logic circuits, such as inverters.

One exemplary embodiment of surrounding gate transistors has been described. As stated above, it would also be possible to make provision for FinFET transistors.

FIG. 3 is a perspective view of one embodiment of a fin 33 comprising portions 33A made of silicon and portions 33B made of silicon-germanium allowing FinFET transistors to be produced. The fin 33 is formed on a substrate of the same type as that used in the process described with reference to FIGS. 1A to 1M. The fin 33 may be formed using a fabrication process analogous to that described with relation to FIGS. 1A to 1M. More particularly, a fin 33 of this type is for example formed by way of the following successive steps:
forming a silicon fin;
masking the portions 33A that are desired to be kept in silicon;
growing silicon-germanium on the exposed portions 33B by means of selective epitaxy;
thermally oxidizing the structure, so that the portions 33B are enriched with germanium atoms and the silicon-germanium is oxidized; and
removing, for example by means of selective etching, the oxidized silicon-germanium and then the patterns protecting the portions 33A.

One advantage of this process is that fins are formed that have portions made of silicon and portions made of silicon-germanium that are aligned with respect to one another and have the same dimensions.

One advantage of this process is that it makes it possible to obtain silicon-germanium channels on the basis of selectively etching silicon-germanium with respect to silicon instead of selectively etching silicon with respect to silicon-germanium, which is generally not very selective.

Particular embodiments have been described. Various variants and modifications will be apparent to those skilled in the art. In particular, the process described with reference to FIGS. 1A to 1M is a process for fabricating transistors but, as a variant, it would be possible to fabricate nanowires or fins comprising silicon portions and silicon-germanium portions for other applications.

Moreover, a process has been described that allows a single strip having alternating portions to be fabricated, but this process of course allows multiple, generally parallel, strips to be formed on one and the same substrate, for example made entirely of silicon or entirely of silicon-germanium or partially of silicon and silicon-germanium. One advantage is that this allows a row of n-channel transistors to be produced next to a row of p-channel transistors.

Various embodiments with various variants have been described above. It should be noted that a person skilled in the art could combine various elements of these various embodiments and variants without exercising inventive skill.

1. A process for fabricating strips or portions of strips of silicon-germanium, comprising the following successive steps:
producing a strip of silicon suspended above a substrate;
surrounding said strip or a portion of said strip of silicon with a layer of silicon-germanium;
carrying out a germanium enrichment of said strip or portion of said strip of silicon by thermal oxidation; and
removing a silicon oxide formed during the thermal oxidation.

2. The process according to claim 1, additionally comprising a step of masking a part of the strip of silicon in order to protect the part of the strip of silicon from the steps of deposition of silicon-germanium and enrichment by thermal oxidation.

3. The process according to claim 1, further comprising forming the silicon-germanium layer by selective epitaxy.

4. The process according to claim 1, wherein a width of the strip of silicon is between 2 and 50 nm and a thickness of the strip of silicon is between 5 and 20 nm.

5. The process according to claim 1, wherein the substrate is an insulator.

6. The process according to claim 1, wherein the thermal oxidation is carried out at a temperature of between 600 and 1200° C.

7. The process according to any claim 1, further comprising removing the silicon oxide by a wet etching process.

8. The process according to claim 1, wherein the silicon strip is a silicon fin.

9. The process according to claim 1, wherein the strip of silicon is a silicon nanowire.

10. A structure, comprising: a plurality of semiconductor nanowires suspended at the same height above a substrate, wherein a first portion of said plurality of nanowires are at least partially made of silicon and a second portion of said plurality of nanowires are at least partially made of silicon-germanium.

11. A structure, comprising: a plurality of semiconductor fins, wherein a first portion of said plurality of semiconductor fins are at least partially made of silicon and a second portion of said plurality of semiconductor fins are at least partially made of silicon-germanium.

12. A process for fabricating a transistor, comprising:
producing a strip of silicon extending above a substrate;
covering a first end and a second end of the strip of silicon by a protection layer;
surrounding a portion of said strip of silicon located between the covered first and second ends with a layer of silicon-germanium;
enriching the portion of said strip of silicon with germanium from said layer of silicon-germanium, said enriching converting said layer of silicon-germanium to a thermal oxide;
removing the thermal oxide;
forming a gate of the transistor surrounding the portion of said strip of silicon that is enriched with germanium; and
forming source and drain regions for the transistor at the first and second ends.
